(19) United States
(12) Patent Application Publication
(10) Pub. No.: US 2003/0180571 A1
(43) Pub. Date: Sep. 25, 2003

(54) Microstructured coatings and materials

(75) Inventor: Jogender Singh, State College, PA (US)

Correspondence Address: McDERMOTT, WILL & EMERY, 600 13th Street, N.W., Wahington, DC, 20005-3096, US

(73) Assignee: The Penn State Research Foundation

(21) Appl. No.: 10/411,127

(22) Filed: Apr. 11, 2003

Related U.S. Application Data
(63) Continuation-in-part of application No. 09/734,756, filed on Dec. 13, 2000.
(60) Provisional application No. 60/170,693, filed on Dec. 14, 1999.

(51) Int. Cl. C23C 16/00; B32B 15/04

(52) U.S. Cl. 428/633; 427/248.1; 427/596; 428/701; 428/472

(57) ABSTRACT

Materials and coatings having submicron microstructure suitable for high temperature applications, such as turbine engines, are disclosed. The materials and coatings are made in an electron-beam, physical vapor deposition (EB-PVD) apparatus and have a microstructure that includes submicron grains and, in some instances, a plurality of substantially discrete columnar layers.

### RELATED APPLICATIONS

This application is a continuation-in-part of co-pending U.S. application Ser. No. 09/734,756 filed Dec. 13, 2000, which in turn claims priority from U.S. Provisional Application No. 60/170,693, filed Dec. 14, 1999. Both applications are incorporated in their entirety herein by reference.

### FIELD OF THE INVENTION

The present invention relates to an apparatus for forming coatings and materials having submicron grain structure for high temperature applications, by electron-beam, physical vapor deposition. The present invention also relates to methods of forming the coatings and materials and has particular utility in the manufacture of turbine engine parts.

### BACKGROUND ART

The drive toward high performance, fuel efficient turbine engines requires higher operating temperatures, which in turn has escalated the demands on engine components parts. Extreme temperatures and severe atmospheric conditions in the combustion section of gas and steam turbine engines result in degradation and structural failures of turbine components and attendant replacement costs. It has been known that the performance and longevity of turbine components is particularly dependent on their operating temperature.

Typical operating temperatures of an aircraft turbine is about 1100-1200° C. Under such excessive heat, unprotected turbine components quickly crack, corrode and ultimately fail. The life of turbine components can be increased by applying oxidation and thermal resistant coatings on parts exposed to such environments. It is known in the prior art to apply a ceramic to a metallic substrate to produce a ceramic thermal barrier coating by physical vapor deposition processes. In this technique, the ceramic is applied onto a previously applied bond coat on the metallic substrate.

Conventional ceramic barrier coating consists of a zirconium oxide (ZrO₂) with 8 wt % yttrium oxide (Y₂O₃) (i.e. 8YSZ). This material has found wide acceptance because of its low density, low thermal conductivity, high melting point, and good thermal shock resistance, i.e., excellent erosion resistant properties. Ceramic thermal barrier coatings produced by electron-beam, physical vapor deposition (EB-PVD) have benefits over other processes.

In U.S. Pat. No. 4,321,311 Strangman reported that a columnar ceramic surface layer circumvents the difference in the coefficients of thermal expansion between the substrate and the coating upon heating. It is believed that the gaps between the individual columns allow the columnar grains to expand and contract without developing stresses that could cause spalling. Upon heating, the substrate expands at a greater rate than the ceramic surface coating and the columnar boundaries between the individual ceramic columns open to accommodate mismatch strains. This limits the stress at the interface between the substrate and the columnar ceramic to a level below that which will produce a fracture of a columnar surface layer.

In U.S. Pat. No. 4,880,614, Strangman et al. further reported that the diffusion of oxygen can be reduced by applying a 1 μm thick alumina (Al₂O₃) coating between the ceramic and metallic bonding layers. Alumina has very low oxygen diffusivity as compared with conventional ceramic layers consisting of such as 8YSZ (10⁻¹⁹ and 10⁻¹¹ m/s at 1000° C., respectively). In spite of the advancements in the coating arts, however, the longevity a coated turbine component is still limited under severe high temperature, oxidative and corrosive environments.

Materials having submicron structure, i.e. having grains of less than one micron, offer superior mechanical, electric and physical properties as compare with materials or coatings with coarse columnar-grained structure. Conventional methods of forming such materials depend, in part, on the materials' constituent composition and intended use. Refractory coatings, or when used as the underlying structural material, are difficult to process and in the past have been formed by an iterative process of partially coating components followed by mechanical grinding, i.e., partially removing coated material, and continued recoating. Such a periodic interruption and mechanical surface grinding and recoating process to a desired thickness is practiced in the manufacturing of refractory material components including Rhenium. This process requires a long lead-time and tends not to be economical.

Hence, a continuing need exists for improved processing to form refractory materials and coatings, such as those that can withstand high temperatures without adverse spallation or otherwise degradation. There is also a need for improved manufacturing throughput of coated parts that does not sacrifice coating performance.

### SUMMARY OF THE INVENTION

Advantages of the present invention are refractory materials and thermal barrier coatings having a particular microstructure that improves their performance including thermal resistance and methods employing an EB-PVD apparatus for making such materials.

Additional advantages and other features of the present invention will be set forth in part in the description which follows and in part will become apparent to those having ordinary skill in the art upon examination of the following or may be learned from the practice of the present invention. The advantages of the present invention may be realized and obtained as particularly pointed out in the appended claims.

According to the present invention, the foregoing and other advantages are achieved in part by a ceramic coating having a microstructure comprising a plurality of substantially discrete columnar layers. The barrier coatings of the present invention advantageously resist thermal conduction through the coating by inhibiting the mean free path available for the conduction of heat thereby protecting an underlying substrate exposed to a high temperature environment. Embodiments of the present invention include a zirconium containing ceramic coating having more than one discrete columnar layers, e.g. from 2 to about 100 discrete columnar layers, wherein each layer has a thickness of about 150 microns (μm) or less, e.g. from about 10 μm to about 100 μm, and wherein columnar grains comprising the columnar layers have an average height of about 150 μm or less, e.g. from about 10 μm to about 100 μm, and an average width of about 10 μm to 60 μm.

Advantageously a thermal barrier coating of the present invention can be formed having a thermal conductivity of less than about 1.8 watts per meter kelvin (W/mK). The inventive thermal barrier coatings are particularly suited for component parts exposed to high temperature environments, such as a part comprising a nickel, cobalt, or iron based alloy having a bond coat on its surface and an oxide layer on the bond coat where the inventive thermal barrier coating is on the oxide layer.

Another aspect of the present invention is directed to an EB-PVD apparatus. The apparatus comprises a vacuum chamber for surrounding a substrate to be coated and having at least one port for evacuating the chamber. The apparatus further comprises: a rotatable arm disposed within the chamber for holding and rotating the substrate; at least one source of material contained within the vacuum chamber; and at least one electron gun connected to the vacuum chamber for striking and evaporating the source material to produce a vapor cloud around the substrate held by the rotatable arm. Embodiments of the present invention include an EB-PVD apparatus that can isolate the substrate from the vapor cloud during the formation of the coating, as by employing a rotatable arm that can position the substrate into and out of the vapor cloud during evaporation of the source material by the electron gun or including a shield disposed in the vacuum chamber that can intermittently be positioned between the vapor cloud and the substrate during the formation of the coating.

In other embodiments of the present invention, the EB-PVD apparatus comprises an additional chamber connected to the vacuum chamber by an actuatable valve or switch for housing finely sized metal oxide particles that can be gravity fed or sprayed onto the substrate during the evaporation of the material in the formation of the coating on the substrate. Another embodiment of the apparatus includes an ion source within the vacuum chamber for ionizing gasses within the chamber to affect the growth morphology of the coating on the substrate.

Yet another aspect of the present invention is directed to methods of forming a coating on a substrate by EB-PVD from at least one material in an EB-PVD chamber. The method comprises introducing the substrate to the EB-PVD chamber; evaporating the material in the chamber to deposit a coating of the material on the substrate; and during the evaporation and deposition of the material, interrupting the formation of the coating on the substrate. Embodiments of the present invention include evaporating a zirconia comprising material and interrupting the formation of the coating on the substrate to form a coating having a plurality of discrete columnar layers by isolating the substrate from the evaporated material for a period of less than about 24 hours, e.g. for a period of time ranging from about 10 sec. to about 1 hour, periodically for about 3 to about 20 isolating/coating intervals.

Additional advantages of the present invention will become readily apparent to those skilled in this art from the following detailed description, wherein only the preferred embodiment of the present invention is shown and described, simply by way of illustration of the best mode contemplated for carrying out the present invention. As will be realized, the present invention is capable of other and different embodiments, and its several details are capable of modifications in various obvious respects, all without departing from the present invention. Accordingly, the drawings and description are to be regarded as illustrative in nature, and not as restrictive.

### BRIEF DESCRIPTION OF DRAWINGS

Reference is made to the attached drawings, wherein elements having the same reference numeral designations represent like elements throughout and wherein:

FIG. 1 is a schematic diagram of a composite structure having a coating with a columnar microstructure.

FIG. 2 schematically illustrates a coating on a substrate in accordance with the present invention.

FIGS. 3a-b show a schematic alloyed matrix in accordance with the present invention.

FIG. 4 schematically illustrates an EB-PVD apparatus in accordance with the present invention.

FIGS. 5a-d are SEM micrographs of an 8YSZ deposited coating on a Pt—Al bond coated substrate showing top morphology (a and b) and showing a fractured surface (c and d).

FIGS. 6a-d are SEM micrographs of a coating in accordance with the present invention showing top morphology (a and b)and showing a fractured surface (c and d).

FIGS. 7a-d are SEM micrographs of an alloyed 8YSZ coating showing top morphology (a and b) and showing a fractured surface (c and d).

FIG. 8 is an SEM micrograph of a graded thermal barrier layer produced by EB-PVD.

FIG. 9 shows a graph of the reflectance performance of a hafnium/yttrium coated substrate comparing the reflectance of a single layer of the coating to that of 40 layers produced by employing a shutter in the EB-PVD chamber to periodically interrupt the deposition of the coating.

### DESCRIPTION OF THE INVENTION

The present invention stems from the discovery that certain manipulation of the microstructure of a ceramic coating results in a significant reduction in the thermal conductivity, improvement in strain tolerance, and good erosion resistance of the coating thereby increasing the longevity of a coated component part exposed to high temperature and corrosive environments. Lower thermal conductivity coatings of the present invention can be achieved without sacrificing other physical and mechanical properties of the coating needed for component parts suitable for high temperature applications.

In order to address the difficulty of reducing the thermal conductivity of coating systems known to have advantageous properties on parts used in high temperature applications, it was necessary to gain an understanding of the factors affecting heat transfer through the protective coating to the part. In crystalline solids, heat is transferred by three mechanisms: (i) electrons, (ii) lattice vibrations, and (iii) radiation. As many materials useful as thermal barriers are electronic insulators, electrons play little part in conducting heat in these systems. Thus to lower the thermal conductivity of the system, reduction in the specific heat capacity, phonon velocity and mean free path, density or refractive index (n) are needed. Specific heat capacity at constant volume for any system is constant above the Debye temperature (zirconia has a value of 25 J/K mol).

One approach to engineer a lower thermal conductivity coating, such as a zirconia-based ceramic coating, is to lower the mean free paths of the heat carriers, their velocity, refractive index and density of the coating on the part. In crystal structures, scattering of phonons occurs when they interact with lattice imperfections. Such imperfections include vacancies, dislocations, grain boundaries, and atoms of different masses. The presence of impurity atoms and ions of differing ionic radius leads to increased anharmonicity and effects phonon scattering by locally distorting the bond length and thus introducing elastic strain fields into the lattice. The effects of such imperfections can be quantified through their influence on the phonon mean free path. This approach has been used by several researchers, for which the phonon mean free path (λp) is defined as:

1/λp=1/λi+1/λvac+1/λgb+1/λstrain

where i, vac, gb stand for intrinsic lattice structure, vacancy and grain boundary, respectively. Among these, the intrinsic lattice structure and strain field have the most significant effect on the phonon mean free path. The total mean free path of the phonon scattering can be reduced by alloying additions (i.e., solid-solution impurities), local strain fields and vacancies in the lattice. For the zirconia-based systems, it has been demonstrated that increasing the level of yttria in the alloy decreases the thermal conductivity due to intrinsic mean free path decreasing with increasing yttria content.

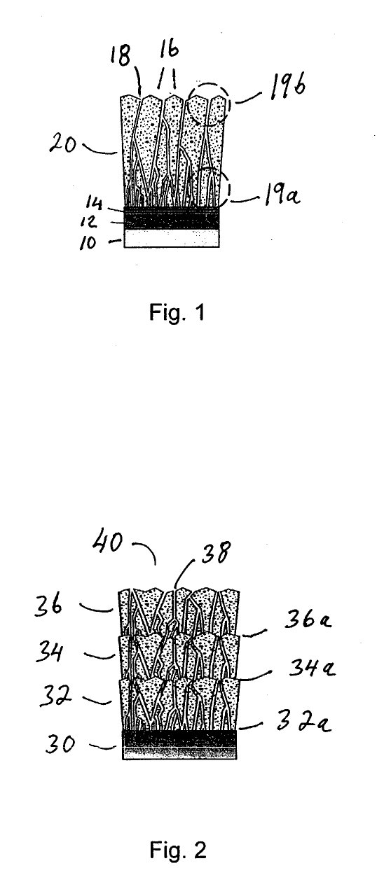

To better understand the affect of microstructure on the thermal properties of ceramic coatings, experiments were conducted employing an electron-beam, physical vapor deposition apparatus (EB-PVD) to form columnar grained ceramic coatings. Referring to FIG. 1, an exemplary composite structure suitable for high temperature applications is illustrated. As shown, substrate 10 has bond coat 12 thereon and oxide layer 14 on bond coat 12. On oxide layer 14 is deposited zirconium coating 20 having a columnar grained microstructure. Columnar grains 16 are oriented substantially perpendicular to the surface of substrate 10 with free spaces 18 between individual columns extending substantially down to oxide layer 14.

Zirconium coating 20 can be produced by EB-PVD and can generally be divided into two zones, 19a and 19b. Inner zone 19a forms the early growth part of a columnar microstructure. The inner zone can be characterized as having a large number of grain boundaries and an increased micro-porosity. It is believed that this is caused by the occurrence of multiple nucleation sites at the beginning of the coating process, which are far greater than at later stages of coating formation. The thickness of the inner zone ranges from about 5 to 10 μm and exhibits lower thermal conductivity (around 1 W/mK). With increasing thickness, the structure can be characterized by a dominant crystallographic texture resulting in an increased thermal conductivity and a continual increase in thermal conductivity as the outer portion of the ceramic layer becomes more crystalline and less porous, i.e. resembling the bulk. In outer zone 19b, the thermal conductivity approaches that of the bulk zirconia (2.2 W/mK).

After experimentation and investigation, it was discovered that by changing the growth processes of a columnar ceramic coating to include a plurality of substantially discrete columnar layers, a significant reduction in the thermal conductivity of the coating can be achieved. In an embodiment of the present invention, the ceramic coating comprises 2 to about 100 substantially discrete columnar layers where each layer has a thickness of about 150 μm or less, e.g. where each layer has a thickness within the range of about 10 μm to about 100 μm.

Illustrated in FIG. 2. is a coating having a microstructure in accordance with an aspect of the present invention. As shown, substrate 30 has ceramic coating 40 thereon, where coating 40 comprises the substantially discrete columnar layers 32 through 36. Each columnar layer comprises columnar grains that are oriented substantially perpendicular to the surface of substrate 30. The columnar layer 40 has an increased number of interfaces 32a, 34a, 36a that have an increased number of grain boundaries and micron-sized intercolumnar gaps 38. In accordance with the present invention, grain sizes vary from a height of about 0.5 to about 4 μm at the interface. In an embodiment of the present invention, each columnar layer comprises columnar grains having an average height of about 150 μm or less, e.g. a height of from about 10 μm to about 100 μm, and an average width of about 10 μm to 60 μm.

The formation of a multi-layered columnar microstructure reduces the mean free path available for the conduction of heat. As shown in FIG. 2, the free spaces between individual columns do not extend substantially uninterrupted through the coating down to the substrate but are substantially blocked or inhibited at the interfaces of adjoining columnar layers. It is believed that the reduced mean path through the barrier coatings of the present invention is principally responsible for the substantially reduce thermal conductivity observed in the inventive coatings. For example, it is believed that the thermal conductivity of a zirconia-yttria coating having a microstructure according to the present invention can be reduced from the theoretical bulk values of 2.2 W/m K to less than about 1 W/m K, e.g., to values in the range of about 0.5 to about 0.9 W/m K.

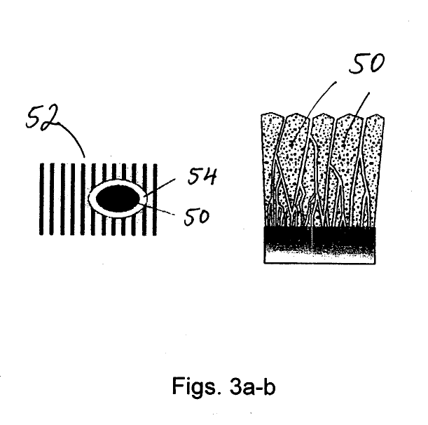

In another aspect of the present invention, the thermal conductivity of the barrier coating can be reduced by creating microporosity through alloying, i.e. the addition of a second metal or metal oxide in the barrier coating matrix that is different from the matrix material. As illustrated in FIGS. 3a-b, the distribution of an additional element 50 in matrix 52 will have a different thermal expansion co-efficient with respect to the matrix material. During thermal cyclic exposure, micro-crack 54 will form around the secondary phase due to lattice mismatch. An increased number of micro-cracks resulting forming a uniform distribution of additional elements in the matrix material will increase the micro-porosity in the matrix thus reducing the thermal conductivity of the alloyed matrix.

The combination of layering at the micron level and introduction of density changes from layer to layer can significantly reduce the thermal conductivity of barrier coatings of the present invention. As mentioned earlier, columnar layer periodicity in the coating in accordance with present invention will significantly reduce both the phonon scattering and photon transport and the local changes in the density will further contribute to phonon scattering and thus reduce the thermal conduction by the lattice and the overall coating.

Although any substrate or part can benefit from the thermal barrier coatings of the present invention, component parts exposed to high temperatures, e.g. temperatures of about 1000° C. to about 1500° C. or higher, are particularly suited for the inventive coatings. For example, the present invention contemplates forming a composite structure comprising a substrate having the inventive thermal barrier coating thereon with or without interlayers between the barrier coating and the substrate.

In practice, the substrate can comprises a nickel, cobalt or iron based alloy or a ceramic material suitable for high temperature applications, such as turbine airfoils or ceramic vanes contained in the combustion compartment of a gas turbine. Component parts comprising metallic single crystal nickel based alloys, nickel based alloy cores with outer shell structures made of refractory metals, such as molybdenum (Mo) or niobium (Nb) based silicides, ceramic-matrix-composites or ceramics, such as silicon nitride (Si₃N₄) can also benefit from the present invention. In an embodiment of the present invention, the substrate can be a superalloy containing hafnium and/or zirconium. In yet another embodiment of the present invention, the substrate can be of a sacrificial material such that when a coating is formed on the substrate and the substrate removed, the coating left behind results in a finished part. It has been discovered that by forming a coating of a refractory material on a sacrificial substrate, and then removing the substrate, net-shaped parts can be manufactured comprising the refractory material.

A bond coat can be formed over the substrate to protect the substrate from oxidation and to provide a firm foundation for the, columnar grain ceramic barrier layer. Typically, bond coat materials comprise a MCrAlY alloy. Such alloys have a broad composition of about 10 wt % to about 35 wt % of chromium; about 5 wt % to about 15 wt % of aluminum; and about 0.01 wt % to about 1 wt % of either yttrium, hafnium, cerium, scandium, or lanthanum, with M being the balance. M is selected from a group consisting of iron, cobalt, nickel, and mixtures thereof. Minor amounts of other elements, such as Ta or Si, can also be present. MCrAlY alloys can be formed on the substrate by conventional methods, such as by EB-PVD through sputtering, low pressure plasma or high velocity oxy fuel spraying or entrapment plating

Alternatively, the bond coat can comprise an intermetallic aluminide such as nickel aluminide or platinum aluminide with or without the MCrAlY alloy. The aluminide bond coat can be applied by standard commercially available aluminide processes whereby aluminum is reacted at the substrate surface to form an aluminum intermetallic compound which provides a reservoir for the growth of an alumina scale oxidation resistant layer. Thus the aluminide coating is predominately composed of aluminum intermetallic e.g., NiAl, CoAl, FeAl and (Ni, Co, Fe) Al phases formed by reacting aluminum vapor species, aluminum rich alloy powder or surface layer with the substrate elements in the outer layer of the superalloy component. This layer is typically well bonded to the substrate.

Aluminiding may be accomplished by one of several conventional prior art techniques, such as, the pack cementation process, spraying, chemical vapor deposition, electrophoresis, sputtering, and slurry sintering with an aluminum rich vapor, entrapment plating and appropriate diffusion heat treatments. Other beneficial elements can also be incorporated into diffusion aluminide coatings by a variety of processes. Beneficial elements include Pt, Pd, Si, Hf, Y and oxide particles, such as alumina, yttria, hafnia, for enhancement of alumina scale adhesion, Cr and Mn for hot corrosion resistance, Rh, Ta and Cb for diffusional stability and/or oxidation resistance and Ni, Co for increasing ductility or incipient melting limits.

Through oxidation an alumina or aluminum oxide layer is formed over the bond coat. Alumina layer provides both oxidation resistance and a bonding surface for the barrier ceramic coating. The alumina layer may be formed before the ceramic coat is applied, during application of the ceramic coat, or subsequently by heating the coated article in an oxygen containing atmosphere at a temperature consistent with the temperature capability of the substrate, or by exposure to a turbine environment. The submicron thick alumina scale will thicken on the aluminide surface by heating the material to normal turbine exposure conditions. The thickness of the alumina scale is preferably submicron (up to about one micron). The alumina layer may also be formed by chemical vapor deposition following deposition of the bond coat.

Alternatively, the bond can be eliminated if the substrate is capable of forming a highly adherent alumina scale or layer. Examples of such substrates are PWA 1487 which contain 0.1% yttrium, Rene N5, and low sulphur versions of single crystal alloys SC180 or CMSX-3.

In accordance with the present invention, a ceramic barrier coating is applied to the substrate by EB-PVD and, as result, has a columnar grained microstructure. The ceramic barrier coating according to the present invention can be any of the conventional ceramic compositions useful as a thermal barrier, such as refractory metal oxides, e.g. zirconia coatings. Zirconium oxides can be stabilized with CaO, MgO, CeO₂ as well as Y₂O₃, e.g. yttria stabilized zirconia, or any other suitable metal oxide. Another ceramic believed to be useful as the columnar type coating material within the scope of the present invention comprises hafnia which can be yttria-stabilized. The particular ceramic material selected should be stable at high temperatures, such as in the high temperature environment of a gas turbine. The following ceramics can be used in accordance with the present invention: zirconia (preferably stabilized with a material such as yttria), alumina, ceria, mullite, zircon, silica, silicon nitride, hafnia, and certain zirconates, borides and nitrides. The total thickness of the ceramic layer can vary from about 1 to about 1000 microns but is typically about 50 to about 500 microns.

Alternative thermal barrier coatings such as composition comprising ZrO₂ with 2.5 wt % of CeO₂, and 8 wt % of Y₂O₃ (YCSZ) have some benefits over 8YSZ (zirconium oxide (ZrO₂) with 8 wt % yttrium oxide (Y₂O₃)) including excellent phase stability at high temperatures and good corrosion resistant properties. Alloying 8YSZ with ceramic oxides including CeO₂ or replacing Y₂O₃ by Sc₂O₃ including ZrO₂-20 wt % Y₂O₃, ZrO₂-25% CeO₂ and ZrO₂-22 wt % CeO₂-7 wt %, Y₂O₃, Fe₃Al₅O₁₂ whose conductivity is comparable with 8YSZ and relatively low oxygen diffusivity.

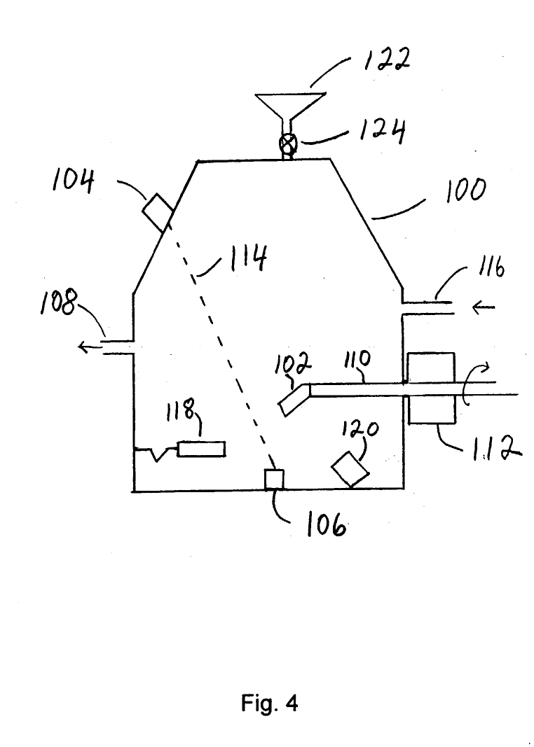

A ceramic coating having a microstructure comprising a plurality of substantially discrete columnar layers in accordance with the present invention can be formed employing an EB-PVD apparatus. An exemplary EB-PVD system of the present invention is shown in FIG. 4. The system comprises vacuum chamber 100 surrounding a metal substrate to be coated 102, at least one electron beam gun 104 and at least one target source of material 106 (e.g. an ingot of zirconia) to be evaporated and subsequently condensed onto the substrate. In an embodiment of the present invention, the EB-PVD apparatus has several, e.g. four to six, electron beam guns having a power of about 45 KW each for improved control of the coating process and several targets, e.g. two to three, for alloying and forming multiple layers of different barrier coatings.

In use, the chamber 100 is evacuated by vacuum pumps (not shown) connected at outlet 108 while substrate 102 is attached to a rotatable support rod 110 and inserted through airlock, or load-lock, chamber 112. The load-lock chamber is typically used as a pre-vacuum chamber for introducing items into the main vacuum chamber. Once the item is introduced into the main chamber, the load-lock chamber can be used to isolate the item from the vapor cloud during evaporation of the target source material.

Since physical vapor deposition is primarily a line-of-sight process, uniform coatings of complex parts, such as a turbine blade or vane, is accomplished by continuously rotating the substrate during the coating process. Coating deposition rate and thickness depend on several parameters such as the material being deposited, the deposition time, chamber pressure, and operating power of the electron guns.

In practice, electron gun 104 is energized to supply a stream of hot electrons 114 to the surface of source 106 causing the evaporation of the source in the form of a vapor cloud (not shown) with subsequent condensation of the source vapors onto the rotating specimen 102. To insure that the deposited vapors are fully oxidized, an oxygen rich gas is usually supplied into the chamber through port 116.

In accordance with the present invention, the ceramic coating prepared in the EB-PVD has a plurality of columnar layers. The plurality of columnar layers can advantageously be formed by periodically interrupting the growth of the columnar coating during the evaporation and deposition process within the EB-PVD chamber. It is contemplated that the isolation of the substrate within the chamber will only temporarily cease the coating process without introducing contaminates.

In an embodiment of the present invention, the growth of the coating can be disrupted by isolating the substrate from the a vapor cloud while the substrate remains in the chamber. In one aspect of the present invention, the substrate can be isolated from the vapor cloud by moving rotatable support rod 110 such that the substrate is out of the vapor cloud. In another aspect of the present invention, the substrate can be isolated from the vapor cloud by introducing shield 118 between the substrate and the vapor cloud. Re-introduction of the substrate to the vapor cloud restarts the growth of columnar grains and a new, discrete columnar layer having a substantially discrete interface on the surface of the previous columnar layer.

The isolation of the substrate from the vapor cloud should be for a time sufficient to form sufficiently new nucleation sites on the coating surface. In an embodiment of the present invention, the growth of the coating can be interrupted for a period of time of about 24 hours or less, e.g. for a period of time of about 10 seconds to about 1 hour. To increase throughput and reduce fabrication costs, it is expected that the interruption period of time will be shortened and include a range from about 10 sec. to about 10 minutes, e.g. from about 30 to about 60 sec.

It is understood that each isolation/re-introduction interval in this embodiment of the invention results in the formation of a new columnar layer and that the larger the number of isolation intervals during the growth process will increase the number of columnar layers. Hence, practicing one aspect of the present invention advantageously permits the formation a plurality of discrete columnar layers, e.g. from 2 to about 100 where the number of layers equals the number of isolation/re-introduction instances and the thickness of each layer corresponds to the length of time that the substrate was exposed to the vapor cloud.

In an embodiment of practicing the present invention, the substrate is taken away from the vapor cloud periodically by translating it into another chamber, i.e., load-lock chamber 112. By translating the sample away from the vapor cloud into the load-lock chamber, it is believed that the temperature of the coated substrate is lowered when within the load lock chamber relative to its temperature during deposition of the coating in the main chamber. Lowering the substrate temperature will reduce the surface mobility of the condensate. When the substrate is re-introduced into chamber 100, condensate will again start growing but with new grains. The size of the grains depends upon many processing conditions including condensation rate, the temperature difference achieved during coating and during interruption, the frequency of interrupting the deposition of material, etc. This process will eliminate both columnar microstructure and inter-columnar gap/porosity.

Given the guidance in the present specification, these variables can be adjusted as described herein with minimal additional experimentation, if any, to achieve improved coatings. For example, a substrate can be periodically interrupted from the continuous vapor flux by translating the substrate away from the vapor cloud for a short time (30-60 seconds). Re-introducing the substrate into the vapor cloud restarts the coating process. During this interruption, the temperature of the substrate can decrease to approximately 700-800° C. from that of about 1000° C. Due to thermal fluctuation of the sample during the deposition cycle, new grain formation occurs. It is believed that the initial nucleation and growth of grains on the polycrystalline substrate will exhibit more randomly oriented grains (i.e., similar to zone 19a of FIG. 1). When the substrate is re-introduced into the vapor cloud, renucleation occur and new grains begin to grow. After each interruption, there is a sharp interface between the new grains and the previous grains. The volume fraction of sharp interfaces depends upon the periodicity, or total number of layers. By increasing the number of layers, the volume fraction of randomly oriented grains will increase and it is anticipated that such a coating will have less crystallographic texturing as compare with a single layer coating of comparable thickness. The microstructure resulting from this process is shown in FIG. 2a. It is contemplated that the total thickness of the multilayered coating can be the same as a single layered coating.

In another aspect of practicing the present invention, the substrate can be isolated from the vapor cloud by using shield 18 or a shutter (not shown). It should be noted that the temperature of the substrate is believed to be the same during this deposition process, i.e., at about 950-1000° C. During this interruption period at elevated temperature, it is believed that the surface mobility of the deposit species contribute towards the surface relaxation in the coating. It is also believed that after each interruption, as the flux deposits on the substrate's surface, new grains will nucleate and grow with continued deposition until the next interruption. Additional porosity near the interface is expected as the grains start to coalesce during the initial coating growth stages with incoming flux from the vapor cloud. The growth orientation of the new grains will remain the same as the previous grains resulting in texturing in the coating. The interface between the old and the new grains will be diffused and it will also contain defects and micro-porosity in the interface. Such interface has shown to improve the thermal conductivity and reflectance of the coatings.

It should be noted that U.S. Pat. No. 6,251,504 describes an EB-PVD process using a shutter. According to-this patent, regermination of the ceramic layer cannot be produced just by interrupting and then resuming deposition using a shutter. This patent does not appear to acknowledge that coatings formed by interrupting and then resuming deposition using a shutter can have improved thermal barrier properties.

Refractory materials such as tungsten, rhenium, hafnium and their alloys are difficult to process due to their high melting point. It is very difficult to produce dense net-shaped components with fine-grained microstructure of refractory materials. Net-shaped components including tubes, thrusters, and mirrors of refractory materials (such as Rhenium material) are currently manufactured only by a CVD process and contain porosity 10-20% (depending processing conditions). Performance of these components is limited due to the formation of large sized grains, however. Large grain size formation is due to the high deposition processing temperature (>1200° C.) and long processing times needed for CVD. In contrast, Rhenium coatings were produced by EB-PVD using a periodic interruption during deposition resulted in the formation of submicron grains. Such small grained structure exhibited higher hardness along with increased strength (30%) in comparison to a rhenium coating made by a conventional CVD process.

In an separate embodiment of the present invention, the growth of the coating can be disrupted by pulsing ionized gas, such as argon, oxygen etc., directed towards the substrate. The pulsed ionized gas can be through ion source 120. Periodic bombardment of the ionized gas will change the growth morphology of the growing columnar layer. It is expected that a sub-columnar structure will be produced having a greater number of interfaces, grain boundaries and micro-porosity resulting in a lower thermal conductivity in practicing the present embodiment.

In another embodiment of the present invention, the growth of the coating can be disrupted by introducing a metal or metal oxide in powder form during the formation of the coating. In one aspect of the present invention, the EB-PVD comprises an additional chamber 122, e.g. a hopper, that is connected to vacuum chamber 100. The additional chamber is used for housing finely sized metal or metal oxide particles that can be gravity fed or sprayed intermittently by an actuatable valve or switch 124 on to the growing ceramic coating to cause new nucleation site during the formation of the coating.

Experimental

Thermal barrier coatings were applied in an industrial prototype EB-PVD unit equipped with six electron-beam guns, wherein each gun had approximately a 45 kW capacity. The chamber employed in the experiments had a size of approximately 900 mm in length, 900 mm in width, and 900 mm in height and could accommodate up to three ingots (approximately 7 cm in diameter and 50 cm in length).

Two electron beam guns were used to evaporate the coating materials and two electron beam guns were used to preheat the substrate indirectly by heating graphite plates. One coating material comprised an ingot having zirconium oxide with 8 wt % of yttrium oxide (8YSZ) and another coating material was an ingot comprised of Niobium (Nb). Coupons were mounted on a horizontal 2 inch diameter shaft which was rotating above the melt pool ingot at a speed of about 6 to 7 revolutions per minute (rpm). The distance between the ingot melt pool and the coupons was about 13 inches. During the evaporation of the 8YSZ ingot, external oxygen was injected into the vapor cloud (at a flow of 100 sccm) to compensate the for loss of oxygen and to maintain the desired stochiometric composition of the 8YSZ. Typical process parameters used for the experiments are given below.

TABLE I

| | |
|---|---|
| Electron beam gun Voltage | about 18 kV |
| Electron beam gun Current | about 1.7 Amps |
| Substrate temperature | about 1000° C. |
| Deposition time | about 1 hour |
| Substrate rotation speed | about 7 rpm |

Four sets of experiments were performed. The thickness and weight of each sample was recorded before and after the coating. After the thickness measurement, samples were cleaned in an ultrasonic bath cleaner with several cleaning solutions. Samples were first cleaned with acetone for twenty minutes, followed by rinsing with de-ionized water and then cleaned with ethyl alcohol for ten minutes. Samples were again rinsed with de-ionized water and then dried with nitrogen gas. The samples were then tack welded separately onto a 1×1 inch stainless steel foil and again cleaned using the ultrasonic bath cleaner and above mentioned solutions. Samples were mounted on a mandrel for 8YSZ deposition. Typical pressure inside the chamber during deposition process was about 10⁻³ Torr to about 10⁻⁴ Torr.

Fractured surface and surface morphology of the coated samples were examined by a scanning electron microscope (SEM). The cross-section of the coated samples was examined by optical microscope and electron microprobe. Phase analysis in the 8YSZ coated samples was determined by X-ray diffraction patterns. A normal Bragg-Brantano (θ/2θ) diffraction step scan was performed over the range of 2θ=15° to 2θ=130° at intervals of 2θ=0.020° for 1 second. The following four types of coatings were prepared and characterized.

I. Standard 8YSZ Coating

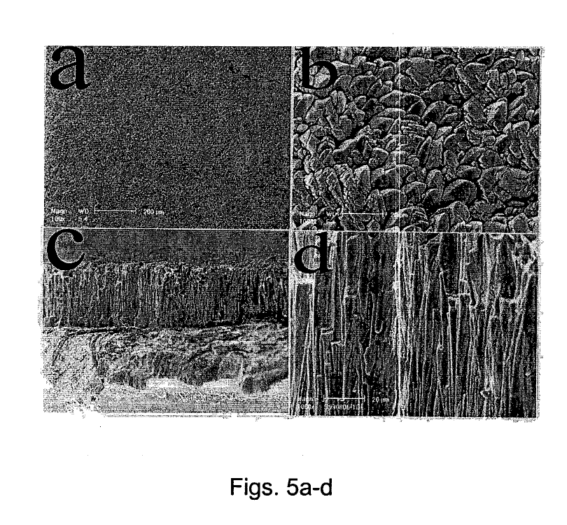

A standard 8YSZ was applied on the mounted coupons using the evaporation parameters as defined in Table I. The coating thickness was found to be about 130-165 μm. The total deposition time was 60 minutes. The typical microstructure of the 8YSZ is shown in FIGS. 5a-d. The top view (FIGS. 5a and 5b) of the 8YSZ shows uniformly faceted microstructure. The fractured surface of the 8YSZ coated samples reveals the side view (FIGS. 5c and 5d) of the coated columnar growth structure. At the 8YSZ/bond coat interface, the size of the columnar grains was found to be relatively small (less than about 1 μm) and increased towards the top surface of the coating. All columnar grains were oriented in the same direction and perpendicular to the substrate. Porosity or spacing was observed between the columnar grains.

II. Discretely-Layered 8YSZ

Discretely-layered 8YSZ coatings were formed by interrupting the continuous deposition of 8YSZ on the coupon samples, i.e., samples were periodically taken out from the vapor cloud during the deposition process while maintained in the EB-PVD system. In particular, the substantially discrete columnar layered structure was formed by removing the sample out of the vapor cloud about every 10 minutes of deposition time and re-entered after about 1 minute (i.e., mounted samples were translated in and out of the vapor cloud 6 times during a total deposition time of 60 minutes). A sharp interface between each columnar layer was produced corresponding to each interruption. In order to see the sharp interface between each columnar layer corresponding to the growth interruptions, a fracture surface was carefully prepared.

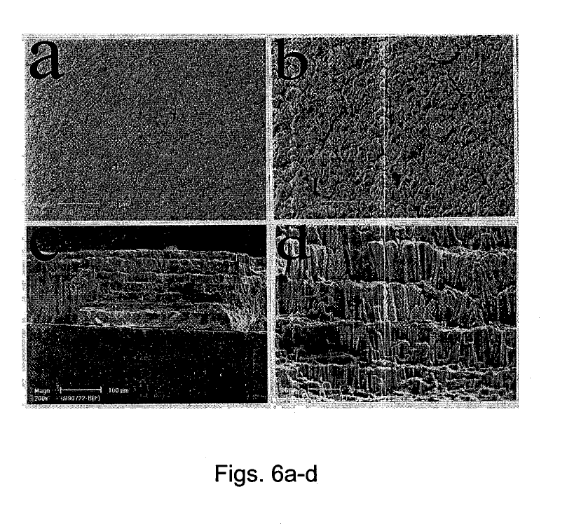

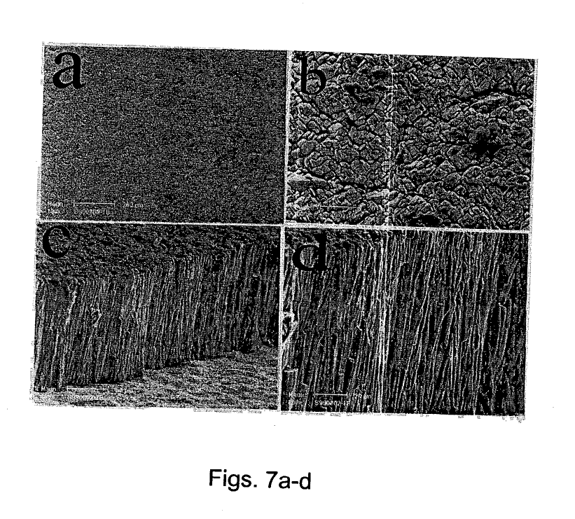

FIG. 6 shows SEM micrographs of the fractured coatings. As seen, the coating comprises six distinct 8YSZ layers. The total thickness of the coating was found to be about 165 μm while each of the distinct layers has a thickness that was approximately the same (about 27 μm). The microstructure of the 8YSZ was found to be columnar by SEM. The micrograph reveals a “step like” image where the coating delaminated at the interfaces.

The top view of all 8YSZ-coated samples showed similar morphologies where the microstructure appeared to have a faceted morphology. Each grain shows a preferred growth in the direction of the coating formation while porosity was observed between 8YSZ grains.

The approximate average grain size of the grains in each columnar layer was substantially the same and ranged from about one to about ten microns. The coating appear very dense compared to standard 8YSZ, which is directly related to the reduction in grain size. By this process, interrupting the growth of the columnar grains results in re-nucleating new grains on the top surface of a previously formed columnar layer.

III. Alloyed 8YSZ with Nb-Oxide

In this experiment, both 8YSZ and Nb ingots were evaporated simultaneously to form an alloyed 8YSZ, (i.e., 8YSZ containing a fine dispersion of Nb in the form of its oxide). During the evaporation of both ingots, oxygen was injected into the vapor cloud to compensate for the loss of oxygen and also to convert Nb into its oxide. All of the samples had a grayish color and there was no sign of coating delamination. The average grain size ranged from one to ten microns. Coating morphology was comparable to standard 8YSZ.

IV. Compositional Graded 8YSZ

The objective of this experiment was to form a compositional graded coating composed of three layers. The first layer comprised a 8YSZ layer followed by an alloyed 8YSZ (i.e., 8YSZ+Nb-oxide) layer, followed by a top layer of 8YSZ. This compositional graded structure was achieved by the evaporation of the 8YSZ ingot for 10 minutes followed by co-evaporation of both 8YSZ and Nb ingots for about 40 minutes and lastly the evaporation of only the 8YSZ ingot for 10 minutes. During the evaporation, oxygen was injected into the vapor cloud to compensate for the loss of oxygen and also to convert Nb into its oxide. The coating deposition was carried out sequentially and continuously without any interruption, therefore there was no sharp interface in the graded coating. Coated samples had a grayish color indicative of oxygen deficiency. The average grain size ranged from one to ten microns. The coating morphology was comparable to the standard and alloyed 8YSZ coatings.

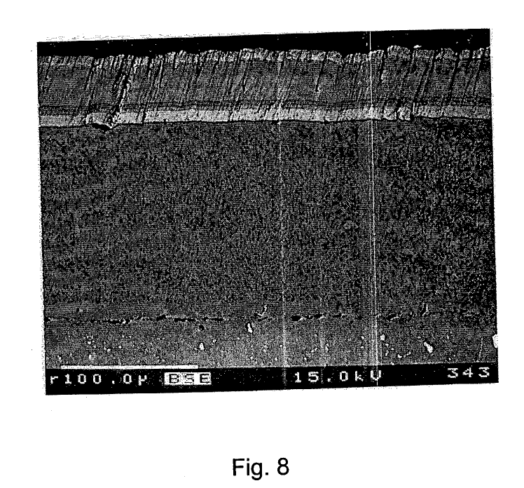

A parallel investigation was also performed using Chromium-oxide as an alternative to Nb-oxide in the development of low conductive thermal barrier coatings. FIG. 8 shows the SEM micrograph of the coating where the first layer is composed of 8YSZ with a thickness of about 5 μm. This layer has a good metallurgical bond to the bond coat, as 8YSZ is known to provide excellent adherence with bond coats, such as MCrAlY and Pt-aluminide. The top layer is composed of another 8YSZ layer with a target thickness of about 15 μm. This was done to provide good erosion resistant properties to the component, as 8YSZ is know to have the best erosion resistant properties among conventional zirconia materials. Sandwiched between the top and bottom 8YSZ layers is a layer comprising 8YSZ and a fine distribution of Cr-oxide to reduce the overall thermal conductivity of the coating. The composite coating exhibited a 15% reduction in thermal conductivity in comparison with 8YSZ. This novel concept opened an opportunity in forming graded coatings for many applications including environmental barrier coatings (EBC) and low conductive 8YSZ without sacrificing other desirable properties such as erosion resistance and adherence properties.

X-ray diffraction (XRD) patterns were obtained for all coating experiments (I to IV). According to the equilibrium phase diagram, 8YSZ should have cubic, monoclinic or tetragonal phases depending upon the processing temperature. All the diffracted peaks from the 8YSZ coatings have been identified as having a tetragonal phase and it is clear that the primary growth direction of the 8YSZ is dominant along the <200> with a maximum diffraction intensity of 100%.

Slight differences were observed in the relative intensities of the diffracting planes. The differences in the relative intensities are a direct result of the degree of texturing where the 8YSZ coating with the composite structure showed the largest deviation in relative intensities. This could be due to many factors including the presence of a relatively large volume fraction of textured equi-axed grains in the layered structure. As each new layer of the 8YSZ is formed, the grains nucleate on the previous 8YSZ layer. Initial grains will grow equally in all directions after which only those grains oriented in the preferred growth direction will continue to grow, resulting in columnar grains. Thus, this layered structure will be composed of textured grains with their dominant growth direction along the <200> as well as semi-textured grains. The sizes of the columns often vary in both length and diameter. The angle of columnar growth direction varies and this results in changes in the relative intensities. XRD of alloyed and graded 8YSZ is similar to the standard 8YSZ, as there is no change in the growth morphology of columnar grains.

Thermal stability of the 8YSZ coatings and its effect on the oxidation rate of the bond coat were determined by exposing buttons coated with each type of coating to an elevated temperature at 1175° C. for 100 hours. Discoloration of certain coated buttons was observed and the results are summarized in Table II below.

TABLE II

| Buttons coated with the | Observed |
|---|---|
| following:¹ | Bluish Color² |
| I Standard 8YSZ prior to exposing | + |
| the button to elevated temperature | |
| I Standard 8YSZ | ++++++ |
| II Discretely layered 8YSZ | + |
| III Alloyed | ++ |
| IV Composite | +++ |

¹The coatings were prepared as described in experimental sections I through IV.
²The symbols represent the relative intensity of bluish color observed. The larger number of symbols indicate a greater intensity of bluish color.

The standard 8YSZ coated button appeared to be relatively dark bluish in color as a result of the oxidation of the underlying bond coat and complete delamination of 8YSZ, i.e., spallation was also observed. In contrast, the color of the discretely layered 8YSZ coated button was still similar to that of the pre-exposure button. Further this button showed limited spallation evidencing the improved protection of the discretely layered 8YSZ coating. The color of the alloyed and compositional graded 8YSZ was relatively lighter bluish in comparison with the standard 8YSZ. On comparing the color of the thermally exposed buttons, the discretely layered 8YSZ button exhibited the best thermal protection coating, followed by the alloyed 8YSZ coating, followed by the composition graded coating and lastly the standard 8YSZ coating.

EDS analysis of the back side of the coatings revealed the presence of Co, Cr, Ni, Al, Zr, and O, elements present in both the bond coating and 8YSZ. However, only Zr, Al and O were detected on the backside of the discretely layered 8YSZ coating further evidencing that the layered structure reduced the amount of bond coating oxidation.

The growth morphology of 8YSZ structure was comparable in all the four sets of experiments. In the discretely layered 8YSZ structure, new columnar grains nucleated and subsequently grew on top of each layer, and remained textured along <200> direction. Thermal exposure experiment shows that the discretely layered 8YSZ coatings exhibited better oxidation resistant properties than the standard, the alloyed and the composition graded 8YSZ coatings.

V. Additional Coating Made by Periodic Interruption

In order to establish a relationship between the thermal conductivity as a function of total number of TBC layers, additional TBC coated samples were produced employing a shutter to periodically interrupt deposition. It was established that the thermal conductivity decreased linearly as a function of increasing number of layers in the TBC. This confirms that periodic interruption of the incoming flux by a shutter results in lower residual strain fields most likely from the incorporation of micro-porosity. A comparative thermal conductivity of EB-PVD 8YSZ coatings produced by three approaches: (i) standard continuous evaporation, (ii) interruption of flux by shutter, and (iii) interruption of flux by moving the substrate in and out of the load lock chamber, showed that interruption of flux (by either method (i) or (ii)) improved the thermal properties of the coatings produced thereby compared to the coating made by the standard continuous evaporation process. For example, it was observed that coatings made by using a shutter to periodically interrupt deposition had increased reflectance as function of the total number of layers. The reflectance was increased from approximately 35% (1-layer) to 45% (20-layers) at a 1 μm wavelength. This suggests that more heat will be reflected from the coatings as the number of layers increases within the TBC. Reflectance of the layered TBC produced by moving the substrate in and out of the load lock chamber was shown to also increase over a coating not so processed. The reflectance increased from approximately 40% to 55% as the total number of sharp interfaces increased from 10 to 40 at 1 μm wavelength.

High Reflectance TBC: In order to obtain a high value of reflectance in the multilayer coatings, a stack of alternate layer of high refractive index and low refractive index materials is used. Typically, the refractive index (n) of ceramic TBC materials are: ZrO₂ (2.10), CeO₂ (2.35), HfO₂ (1.98), Al₂O₃ (1.60), SiO₂ (1.95), Y₂O₃ (1.82). Similarly, refractive index of monolithic materials can be changed by forming alternate layers of high and low density structures, i.e., modulated microstructure with density variation. An advantage of inhomogeneous antireflection coatings is that they are not sensitive to the angle of incidence. By controlling the thickness of each layer, reflectance of the coating can be altered over a wide wavelength range. This concept was demonstrated using two materials of different composition and refractive index as described below.

A multilayer coating with alternate layers of 8YSZ and Al₂O₃ by co-evaporation EB-PVD was formed. The thickness of each layer was tailored to achieve high hemispherical reflectance over a wide wavelength range. Under this effort two ingots (8YSZ and Al₂O₃) were co-evaporated in the EB-PVD chamber with a partition between two ingots. Evaporation rate of each ingot was controlled to get the desired thickness of each layer. Thickness of each Al₂O₃ layer was varied from about 75 nm to 100 nm while the thickness of 8YSZ remained the same, about 400 nm. The reflectance of the coating varies from 75% to 50% over a wide range of wavelengths. This preliminary experiment clearly shows that the reflectance of the coatings can be tailored to achieve high reflectance over a wide wavelength range by controlling the thickness of a Al₂O₃ and 8YSZ layers.

Impact Energy Dissipation: It is anticipated that the layered TBC will also offer additional benefits toward improved impact resistance properties. It is well documented in the literature that layered structures such as composites, absorb more impact force/energy as compared to monolithic materials by dissipating these forces along interfaces. Therefore, the layered structures should exhibit better impact resistant properties, such as erosion resistance.

HfO₂-Based Ceramic Coatings: An effort was undertaken to define the process window in applying HfO₂-40 wt. % ZrO₂-20 wt. % Y₂O₃ and HfO₂-27 wt. % Y₂O₃ coatings on Pt-aluminide bond coated buttons. Coatings were applied using the standard process parameters used for 8YSZ, i.e., substrate temperature of about 1000° C., external oxygen supply pressure of about 150 sccm, rotation speed of about 7 rpm, and a distance between the sample and the evaporation source of about 12 inches. The HfO₂-40 wt. % ZrO₂-20 wt. % Y₂O₃ coatings exhibited columnar grained microstructure with relatively high density as compare with 8YSZ. HfO₂-27 wt. % Y₂O₃ coatings were also deposited under the similar processing parameters and the coating exhibited a relatively denser coating in comparison with the HfO₂-40 wt. % ZrO₂-20 wt. % Y₂O₃. This can be explained on the basis of homologous temperature, vapor pressure and evaporation rate. In general, it is relatively difficult to get a good, stable melt pool for HfO₂-based ingots due to the lower thermal conductivity. Typical homologous temperature of 8YSZ is approximately 0.4-0.5 Tₘ to get columnar microstructure with desired inter-columnar spacing. When the substrate temperature was increased from 1000 to 1100° C., the HfO₂-27 wt. % Y₂O₃ coatings exhibited more columnar microstructure. Correspondingly, texturing of the coating growth also changed as evident in the X-ray diffraction pattern.

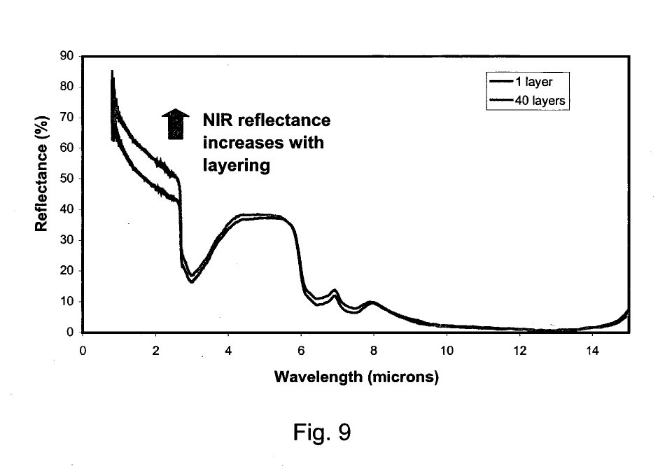

The thermal conductivity of the HfO₂-40 wt. % ZrO₂-20 wt. % Y₂O₃ and HfO₂-27 wt. % Y₂O₃ coatings were measured by a CO₂ laser technique at NASA-GRC. The thermal conductivity of the coatings were compared. The thermal conductivity of HfO₂-27 wt. % Y₂O₃ was found to be the lowest (1.1 W/m-K). In order to further reduce the thermal conductivity of HfO₂-27 wt. % Y₂O₃, layering was employed. The thermal conductivity of HfO₂-27 wt. % Y₂O₃ was further reduced as a function of forming a number of layers. Layering in the HfO₂-27 wt. % Y₂O₃ coatings has also exhibited an influence on the hemispherical reflectance properties as they increased from 50% to 65% as shown in FIG. 9. These findings reconfirm previous findings with the 8YSZ coatings made by interruption. That is, improvements in the thermal properties of these coatings are likely the result of microstructural effects (and not due to composition) which can easily be adopted to other TBC systems.

These experiments help to demonstrate that tailoring microstructure and composition of TBC in accordance with the methods described herein will permit the engineering of new TBC materials with lower thermal conductivity, higher reflectance properties, as well as better impact resistance properties. It is expected that layered TBC structures made in accordance with the present invention will exhibit a reduction in thermal conductivity by at least 12-15%, an increase in reflectance of at least 12-15% and higher reflectance over a greater range of wavelengths as compared to the same coating made without periodic interruption. The present invention is applicable to the manufacture of various types of coatings microstructure and compositions, particularly low thermal barrier coatings having thermal conductivities of about 1 W/m K and under.

VI. Net-Shaped Parts

Rhenium, as a pure refractory metal, is a very attractive material for high temperature structural and energy system applications such as solar powered rocket engines, heat exchangers, space and missile propulsion systems. Rhenium has many advantages over other materials including tungsten. It offers excellent erosion resistance for components in high-temperature rocket engines and hot gas-valves. Rhenium has the second highest melting temperature, tungsten being higher. Unlike tungsten, it has a ductile-to-brittle transition temperature well below room temperature. Among the refractory metals, rhenium has the greatest tensile and creep-rupture strength at elevated temperatures. Rhenium cold work hardens and may only be worked 5-10% before requiring high temperature annealing to fully re-crystallization.

It is difficult to manufacture net-shaped components made of refractory metals, such as rhenium. Typically, components are fabricated by either powder metallurgy (P/M) or chemical vapor deposition (CVD). However, these techniques have various limitations. The present invention overcomes many of the limitations of conventional processes by forming coatings of refractory materials on a sacrificial substrate, which is subsequently removed.

For example, if the coating is deposited on a sacrificial mandrel and the mandrel is removed, the resultant structure will be in the form of a net-shaped component. Performance of the component depends upon its microstructure and its porosity. For high structural integrity, it is preferable to produce components having fine-grained microstructure with minimum porosity.

Fabrication of Rhenium plate: A rhenium ingot was used as a source material that was supplied by Rhenium Alloys Inc. (density 98% and purity 99.99%). A focused high-energy electron beam was used to evaporate the rhenium ingot in the coating chamber of an EB-PVD system and deposited on a set of graphite plates. During deposition process, the graphite plates were indirectly heated up to 1000° C. Coated plates exhibited higher hardness (283VHN) in comparison with a CVD produced rhenium plate, which had a hardness of 245VHN. Using the Hall-Patch equation along with the grain size and hardness, it is predicted that the Re-plate will exhibit a 30% improvement in mechanical properties as compared with CVD Re-plate. Rhenium plates made by EB-PVD were found to be free from impurities such as copper or other materials from vacuum chamber. In addition, these plates exhibited textured grain growth with micron and submicron sized microstructure. The coefficient of thermal expansion (CTE) of the EB-PVD Re-plates were comparable to those made by CVD. It is anticipated that the microstructure of the Re plate produced by ion-beam assisted EB-PVD would exhibit much finer grain microstructure with superior mechanical properties. Optical micrographs showed a 40 mil thick rhenium plate deposited by EB-PVD to have a tensile strength 72 KSI and hardness 283VHN. Typical tensile strengths of a conventional CVD Re-plate is 50 KSI and hardness 245VHN.

Fabrication of rhenium coated graphite balls: Applying uniform rhenium coating on graphite balls (or cores) is another example of the versatility of the present invention. About 18 graphite cores were simultaneously charged into a cylindrical cage. The cage was fabricated using molybdenum wires and plates. The cylindrical cage was rotated at 7-10 rpm above a melt pool of rhenium vapor. During the deposition process, the cores were heated to about 1000° C. and simultaneously bombarded with ionized argon gas to obtain a dense microstructure. After applying rhenium to the full coating thickness, eighteen coated cores were simultaneously polished in a laboratory vibromet-polishing unit to the surface finish <Ra8. All coated cores exhibited uniform coatings with 100% concentricity, which was measured by a co-ordinate measuring machine (CMC). It was observed that there were more than 250 micro and submicron grains through the coating thickness with much finer grained structure in the EB-PVD produced coatings as compared to a coating made by conventional CVD process. It has been projected that the cost of manufacturing rhenium-coated cores by EB-PVD would be less than 50% of the current CVD process. A cross-section of the Rhenium coated core exhibited dense coatings with nano and submicron sized grained microstructure.

For comparison, 2-4 graphite cores were coated simultaneously by conventional CVD with periodic changing the angle of rotation with respect to the flow direction of the rhenium molecules. Rejection rate is very high (>75%) due to concentricity and non-uniform coating thickness on graphite balls. The conventional CVD process yielded only 2-5 grains through a 30 mil coating.Fabrication of Rhenium tubes: A similar effort was undertaken in manufacturing of pilot valve rhenium (Re) tubes with a wall thickness 10 mil and length of 8-10 inches. Such tubes are manufactured using molybdenum (Mo) tubes as a mandrel on which rhenium is deposited. The Mo mandrel is removed by chemical dissolution leaving behind the skin of the coating, i.e., rhenium in tubular form. Currently, Re tubes are manufactured by CVD. The main draw back of CVD is that the Re tube made thereby contained only 2-4 grains through the wall thickness, which does not provide an adequate number of grains for welding and bending applications or to accommodate high pressures. Also, CVD process is limited in manufacturing of tubes (2-3 at a time). In a cross-section of a rhenium tube produced by CVD, 1-3 grains are observed through 10 mil wall thickness.

Rhenium Tubes: A sacrificial molybdenum (Mo) mandrel was used in manufacturing of Re tubes. Eleven Mo mandrels were mounted simultaneously for applying Re coatings in an EB-PVD system and the system evacuated. Mo mandrels were periodically rotated to get uniform coating thickness across their diameter and heated indirectly to 1000° C. during Re deposition. The cross-section of the rhenium coated Mo mandrel was shown to be very uniform around the Mo tube. Optical microstructure of the coated tube exhibited more than 40-50 grains through the a 10 mil wall thickness, which is 10 times more grains than can be achieved by conventional CVD processes. Nano-grained and submicron grained microstructure was observed through the rhenium wall thickness.

Fabrication of Net-shaped Thruster: Net-shaped thruster fabrication was demonstrated using titanium as an evaporant material instead of rhenium by EB-PVD. Due to high flexibility in the EB-PVD process, two thrusters (mirror image) were made at the same time during deposition process. Results were very promising with uniform coating thickness along a graphite mandrel.

Microstructural evolution of Rhenium plate-after thermal exposure: Tailoring microstructure of the coating is important for the desired mechanical properties. One of the approaches adopted in tailoring microstructure was controlling the vapor incidence angle (VIA). Nucleation and subsequent growth of the coating depends upon the VIA. Coatings grow is generally parallel to incoming flux direction. A substrate above the melt pool (referred as C-center) exhibited coating with grains perpendicular to the substrate surface, i.e., growth direction parallel to incoming flux. Similarly, substrates located at an angle with respect to the melt pool exhibited grain growth parallel to VIA, i.e., parallel to incoming flux (referred as L-left and R-right). Periodically changing the location of the substrates during deposition process (from L to R and R to L) exhibites a zig-zag grain growth.

Microstructure and hardness of the deposited rhenium plate was altered by exposing at elevated temperatures. Grain size of the as deposited rhenium was about 5-7 μm and corresponding hardness was 275VHN. Such high hardness could be associated with fined grained microstructure and residual stresses. On subsequent annealing at elevated temperatures (1100-1450 C.), grain growth was observed and correspondingly, softening in the rhenium plate was observed as evidenced by reduction in hardness from 275 to 225VHN.

The EB-PVD process can be used in the fabrication of net-shaped components in a cost effective manner with superior microstructure and mechanical properties. It is predicted that the cost of rhenium components manufactured by EB-PVD process would be 50% less as compare to current CVD and powder-HIPP technologies. This is a robust process with a high degree of flexibility in controlling composition and microstructure of the components. Unlike CVD process, no intermediate machining is required in destroying columnar microstructure, rather much finer grained microstructure is achievable in the EB-PVD. Unlike powder metallurgy processes followed by HIPP, no surface machining is required to get desired surface finish. This is a one step process.

The present invention can be practiced by employing conventional materials, methodology and equipment. Accordingly, the details of such materials, equipment and methodology are not set forth herein in detail. In the previous descriptions, numerous specific details are set forth, such as specific materials, structures, chemicals, processes, etc., in order to provide a thorough understanding of the present invention. However, it should be recognized that the present invention can be practiced without resorting to the details specifically set forth. In other instances, well known processing structures have not been described in detail, in order not to unnecessarily obscure the present invention.

Only the preferred embodiment of the present invention and but a few examples of its versatility are shown and described in the present disclosure. It is to be understood that the present invention is capable of use in various other combinations and environments and is capable of changes or modifications within the scope of the inventive concept as expressed herein.

What is claimed is:

1. A ceramic coating having a microstructure comprising a plurality of substantially discrete columnar layers overlying one another so as to substantially prevent any direct path from the top of the coating to the bottom of the coating, wherein each substantially discrete columnar layer has a thickness of about 150 μm or less and wherein each substantially discrete columnar layer comprises columnar grains having an average height of about 100 μm or less.

2. The ceramic coating of claim 1, wherein the thermal conductivity of the ceramic coating is about 1.8 W/mK or less.

3. A method of forming a coating on a substrate by electron beam, physical vapor deposition (EB-PVD) from at least one material in an EB-PVD chamber, the method comprising:
introducing the substrate to the EB-PVD chamber;
evaporating the at least one material in the EB-PVD chamber under vacuum;
depositing the evaporated at least one material on the substrate; and
during the deposition of the at least one material, periodically interrupting the deposition of the at least one material on to the substrate by periodically isolating substantially the entire substrate from the evaporating at least one material while maintaining the substrate under vacuum to form a layered coating of the at least one material on the substrate.

4. The method according to claim 3, comprising isolating the entire substrate from the evaporating at least one material.

5. The method according to claim 3, comprising isolating the substrate from the evaporating at least one material for a period of about 24 hours or less.

6. The method according to claim 3, comprising bombarding the substrate with pulsed ionized gas.

7. The method according to claim 3, comprising isolating the substrate by interposing an object between the evaporating at least one material and the substrate.

8. The method according to claim 7, comprising interposing the object between the evaporating at least one material and the substrate from between 2 to about 100 intervals.

9. The method according to claim 8, comprising forming a layered hafnium containing coating.

10. The method according to claim 3, comprising moving the substrate away from the evaporated material to interrupt the formation of the coating.

11. The method according to claim 3, comprising evaporating a second material to form an alloyed coating on the substrate

12. The method according to claim 3, wherein the substrate comprises a nickel, cobalt, or an iron based alloy and a bond coat and the at least one material comprises zirconium, cesium, hafnium aluminum, silicon, or yttrium.

13. The method according to claim 3, comprising moving the entire substrate away from the evaporating material and reintroducing the substrate to the evaporating material for several isolation/reintroduction intervals to periodically interrupt the deposition of the at least one material on the substrate to form a coating having a plurality of discrete columnar layers overlying one another.

14. The method according to claim 13, comprising depositing the plurality of columnar layers wherein each columnar layer comprises columnar grains having an average height of 150 m or less.

15. The method according to claim 13, comprising evaporating a zirconia comprising material and interrupting the deposition of the material on the substrate to form a coating having a plurality of discrete columnar layers by isolating the substrate from the evaporating material for a period of time ranging from about 10 seconds to about 10 minutes periodically for 3 to about 10 intervals.

16. A method of forming a net-shaped part by electron beam, physical vapor deposition (EB-PVD), the method comprising:
introducing a sacrificial substrate to an EB-PVD chamber;
evaporating a material in the chamber with an electron gun under vacuum;
depositing the material on the sacrificial substrate; and
removing the sacrificial substrate to form a net-shaped part of the deposited material.

17. The method according to claim 16, comprising evaporating a rhenium containing material and forming a rhenium containing net-shaped part.

18. The method according to claim 16, comprising evaporating tungsten, rhenium, hafnium or an alloy thereof as the material.

19. An electron-beam, physical vapor deposition apparatus comprising:
a vacuum chamber for surrounding a substrate to be coated and having at least one port for evacuating the chamber;
a rotatable arm disposed within the chamber for holding and rotating the substrate;
at least one source of material contained within the vacuum chamber;
at least one electron gun connected to the vacuum chamber for striking and evaporating the source material to produce a vapor cloud around the substrate held by the rotatable arm; and
a second chamber connected to the vacuum chamber by an actuatable valve or switch for housing finely sized metal oxide particles that can be gravity fed or sprayed onto the substrate during the evaporation of the material in the formation of the coating on the substrate.
